(19) United States
(12) Patent Application Publication
(10) Pub. No.: US 2025/0129477 A1
(43) Pub. Date: Apr. 24, 2025

(54) SYSTEM FOR ADJUSTING PROCESS CHAMBER COMPONENT TEMPERATURE

(71) Applicant: Applied Materials, Inc., Santa Clara, CA (US)

(72) Inventors: Zhepeng CONG, San Jose, CA (US); Vinh N. TRAN, San Jose, CA (US); Yong ZHENG, San Jose, CA (US); Vishwas Kumar PANDEY, Madhya Pradesh (IN); Ala MORADIAN, Sunnyvale, CA (US); Rajeev CHAVAN, Bangalore (IN); Abraham PALATY, San Jose, CA (US)

(21) Appl. No.: 18/916,299

(22) Filed: Oct. 15, 2024

(30) Foreign Application Priority Data
Oct. 20, 2023 (IN) 202341071806

(51) Int. Cl. C23C 16/455; C23C 16/44

(52) U.S. Cl. CPC C23C 16/45591; C23C 16/4408; C23C 16/4411

(57) ABSTRACT

In one or more embodiments, a semiconductor processing kit includes a reflector assembly. The reflector assembly configured to support one or more sensing devices therein. The reflector assembly includes a body having a top surface and a volume at least partially defined by an inner surface and an outer surface. The reflector assembly further includes a baffle and a fluid channel disposed within the baffle. The fluid channel is configured to flow a fluid to adjust a temperature of the one or more sensing devices. A ring is disposed on the top surface. The ring is configured to reduce a flow of a fluid into the volume. A reflector is concentrically disposed radially outward of the outer surface and creates a gap that allows the fluid to partially flow between the inner surface of the reflector and the outer surface.

### CROSS-REFERENCE TO RELATED APPLICATIONS

This application claims priority to India Provisional Patent Application No. 202341071806 filed on Oct. 20, 2023 the contents of which are incorporated herein by reference in their entirety.

### BACKGROUND

### Field

The present disclosure relates to systems, apparatus, and methods for efficient semiconductor chamber component temperature control.

### Description of the Related Art

Semiconductor substrates are processed for a wide variety of applications, including the fabrication of integrated devices and microdevices. During processing, various parameters can affect the uniformity of material deposited on the substrate. For example, undesired depositions on chamber components can affect the temperature of the substrate and/or temperature(s) of processing chamber component(s), which can affect deposition uniformity, processing rates, product yields, and product waste. Chamber cleaning of undesired depositions is time intensive and directly affects product throughput. Furthermore, minimizing chamber cleaning downtime of chamber components can be difficult and/or expensive.

Therefore, a need exists for improved temperature control to minimize undesired depositions onto chamber components.

### SUMMARY

The present disclosure relates to systems, apparatus, and methods for adjusting the temperature of a chamber component, such as a chamber window, for semiconductor manufacturing.

A processing kit, a system, and a method for semiconductor component temperature control are described herein.

In one or more embodiments, a semiconductor processing kit includes a reflector assembly. The reflector assembly configured to support one or more sensing devices therein. The reflector assembly includes a body having a top surface and a volume at least partially defined by an inner surface and an outer surface. The reflector assembly further includes a baffle and a fluid channel disposed within the baffle. The fluid channel is configured to flow a fluid to adjust a temperature of the one or more sensing devices. A ring is disposed on the top surface. The ring is configured to reduce a flow of a fluid into the volume. A reflector is concentrically disposed radially outward of the outer surface and creates a gap that allows the fluid to partially flow between the inner surface of the reflector and the outer surface.

In one or more embodiments, a processing system includes a chamber body comprising one or more sidewalls at least partially defining an internal volume. A substrate support is disposed in the internal volume. The processing system further includes a lid and a reflector body supported by the lid and at least partially defining a volume. An arresting ring is disposed between the reflector body and the lid. The arresting ring is configured to reduce a flow of a fluid into the volume. A ring reflector is concentrically disposed radially outward of the reflector body and defines a gap that allows the fluid to partially flow between the ring reflector and the reflector body.

In one or more embodiments, a method of adjusting a temperature of a processing chamber component includes flowing a purging fluid into an internal volume separate from a processing volume and flowing a first portion of the purging fluid through a gap between a reflector assembly and a ring reflector disposed within the internal volume. The method further includes flowing a second portion of the purging fluid through a separator disposed within the internal volume and radially outward of the ring reflector and exhausting the first portion of the purging fluid and the second portion of the purging fluid.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2 is a schematic view of the temperature measurement sites by the sensing devices shown in FIG. 1, according to one or more embodiments.

FIG. 3 is a schematic cross-sectional view of a reflector assembly, according to one or more embodiments.

FIG. 4 is a schematic enlarged view of the processing chamber shown in FIG. 1, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to an apparatus and system for adjusting the temperature of a chamber component (e.g., a chamber window) to improve processing efficiency, for example, by reducing the need to clean one or more components utilized for semiconductor manufacturing.

Variations in the surface temperature of chamber components during processing leads to undesired deposition on those chamber component surfaces. For example, overheating of a chamber upper body, which houses the heating sources, may be cooled by, for example, a variable speed blower (VSB) flowing air within the upper body during processing. The flow of air inadvertently affects, for example, a chamber window surface temperature within the processing volume. Increases in the chamber window surface temperature leads to an undesired deposition of process gases on a surface of the window within the process volume. These undesired depositions require cleaning of the chamber components before additional processing can be performed within the processing chamber.

Chamber clean operations have a significant impact on processing rates. For example, long temperature stabilization periods, long cleaning gas exposure within the process volume, and purging cycles in preparation for processing operations are time-consuming and significantly reduce production throughput. Efficiency of the chamber component (e.g., chamber window) clean with hydrochloric acid (HCl) is strongly surface temperature dependent. Efforts to reduce cleaning frequencies involve strategic process gas preheating to encourage material deposition in a desired location and/or other methods to deter undesired depositions. When implementing these deterrence methods, maintaining surface temperatures in order to reduce undesired deposition on chamber components surfaces can be challenging.

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

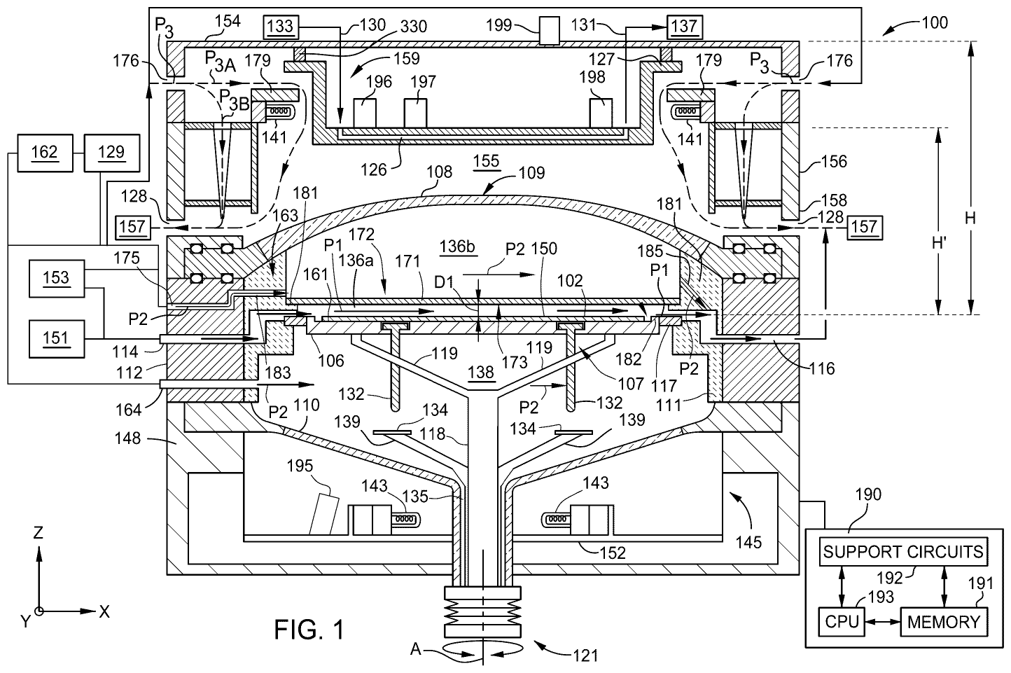

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. The upper body 156 is fluidly connected to one or more purge gas inlets P (e.g., a plurality of purge gas inlets) and one or more gas exhaust outlets 128. The one or more purge gas inlets 176 are illustrated as being disposed through a chamber lid 154. However, it is contemplated that the one or more purge gas inlets 176 may be disposed around the chamber on the upper body 156 for strategic flow pathways. The one or more purge gas inlets 176 are disposed above the one or more gas exhaust outlets 128. Purge gas flow within upper heat source module 155 is represented by P3, discussed below. Disposed within the chamber body is a substrate support 106, an upper window 108 (such as an upper dome), a lower window 110 (such as a lower dome), a plurality of upper heat sources 141, and a plurality of lower heat sources 143. The upper window 108 has a central portion 109. In one or more embodiments, the upper heat sources 141 include upper lamps and the lower heat sources 143 include lower lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein. Furthermore, the placement of the lamps in FIG. 1 is for visual representation and may be located in other strategic areas with an upper heat source module 155 and/or a lower heat sources module 145.

The substrate support 106 is disposed between the upper window 108 and the lower window 110. The substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the upper window 108 and a lid 154. The plurality of upper heat sources 141 form a portion of the upper heat source module 155. The lid 154 includes a support configured to suspend an inner reflector 127 that houses a plurality of sensor devices 196, 197, 198 disposed therein or thereon and configured to measures temperature(s) within the processing chamber 100.

Sensor devices 196, 197, 198, 199 can be disposed on or within the lid 154, shown by height H (with respect to the top surface 150 of the substrate 102). However, by disposing the sensor devices 196, 197, 198 in the inner reflector 127, as shown in FIG. 1, the sensor devices 196, 197, 198 can be closer to the sensing targets and can facilitate an accurate measurement. In one or more embodiments, the sensor devices 196, 197, 198 are disposed in the inner reflector 127 to position the sensors at a height H′. The height H may be about 370 millimeters to about 410 millimeters, such as about 380 millimeters to about 400 millimeters, such as, for example 390 millimeters. The height H′ may be about 200 millimeters to about 240 millimeters, such as about 210 millimeters to about 230 millimeters, such as about 220 millimeters. By placing the sensor devices 196, 197, 198 within the inner reflector 127, the difference between height H and height H′ is about 150 millimeters to about 190 millimeters, such as about 160 millimeters to about 180 millimeters, such as about 170 millimeters.

In one or more embodiments, a sensor device(s) 199 monitors the temperature of the inner reflector 127. The inner reflector 127 includes a cooling line 130 within the inner reflector 127 that facilitates a reflector cooling operation, preventing the plurality of sensor devices 196, 197, 198 from overheating. In one or more embodiments, the cooling line follows along a snake pattern within a channel 126 embedded in the surface of the reflector configured to surround the base of the plurality of sensor devices 196, 197, 198. In one or more embodiments, the channel 126 can be an open channel including a recessed groove having a bottom surface and two sidewalls. In one or more embodiments, the channel 126 can be machined into an inner surface of the inner reflector 127. In one or more embodiments, the channel 126 and can be an embedded enclosed channel. For example, the channel 126 can be disposed within one or more hollow tubes embedded into the inner reflector 127.

The reflector cooling operation can be a continuous, pulsed, and/or timed flow of a cooling fluid through cooling line(s) 130, 131, such as water, refrigerant, or other cooling medium (e.g, cooling flush). Furthermore, the cooling line(s) 130, 131 can help stabilize the inner reflector 127 temperature profile to be less than about 55 degrees Celsius, facilitating fewer thermal variations and less production waste from unstable processing. The cooling line inlet 130 and the cooling line outlet 131 are fluidly connected to a cooling source 133 and a disposal site 137. A lower sensor device 195 is configured to measure temperature(s) within the processing chamber 100. In one or more embodiments, each sensor device 195, 196, 197, 198, 199 is a pyrometer. In one or more embodiments, each sensor device 195, 196, 197, 198, 199 is an optical sensor device, such as an optical pyrometer. The present disclosure contemplates that sensors other than pyrometers may be used. Each sensor device 195, 196, 197, 198, 199 is a single-wavelength sensor device or a multi-wavelength (such as dual-wavelength) sensor device. The lower sensor device 195 is disposed adjacent to the floor 152.

In one or more embodiments, the process chamber 100 includes any one, any two, or any three of the five illustrated sensor devices 195, 196, 197, 198, 199.

In one or more embodiments, the process chamber 100 includes one or more additional sensor devices, in addition to the sensor devices 195, 196, 197, 198. In one or more embodiments, the process chamber 100 may include sensor devices disposed at different locations and/or with different orientations than the illustrated sensor devices 195, 196, 197, 198, 199. For example, one or more of the sensor devices 195, 196, 197, 198, 199, may be disposed in or on the lid 154 and/or disposed in or on the inner reflector 127. Placement of the sensor devices 195, 196, 197, 198, 199 nearest the measured component enables more accurate and/precise sensing by reducing the distance between the sensor and the object to be measured. By reducing the distance between the sensor and the object to be measured, fewer external parameters may affect the sensing. For example, a reduced distance may provide significantly less thermal flow between the sensor and the measured component, providing a more stable reading as compared to implementing greater distances between the sensor and the measured component.

The plurality of lower heat sources 143 are disposed between the lower window 110 and a floor 152. The plurality of lower heat sources 143 form a portion of the lower heat source module 145. The upper window 108 is an upper dome and/or is formed of an energy transmissive (e.g., thermally transmissive) material, such as quartz. In one or more embodiments, upper window 108 at least partially physically separates an upper portion of the process chamber 100 (in which the upper heat source module 155 is disposed) from the isolated portion 136b of the upper volume 136. The lower window 110 is a lower dome and/or is formed of an energy transmissive (e.g., thermally transmissive) material, such as quartz. The present disclosure contemplates that the upper window 108 and/or the lower window 110 can be replaced with another material, such as an opaque material for example. As such, the upper window 108 can be referred to as an upper plate and/or the lower window 110 can be referred to as a lower plate.

An upper volume 136 and a purge volume 138 are formed between the upper window 108 and the lower window 110. The upper volume 136 and the purge volume 138 are part of an internal volume defined at least partially by the upper window 108, the lower window 110, and one or more liners 111, 163.

The internal volume has the substrate support 106 disposed therein. The substrate support 106 includes a top surface on which the substrate 102 is disposed. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the upper volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164, and one or more gas exhaust outlets 116. The one or more gas inlets 114 and the one or more purge gas inlets 164 are disposed on the opposite side of the flow module 112 from the one or more gas exhaust outlets 116. A pre-heat ring 117 is disposed below the one or more gas inlets 114 and the one or more gas exhaust outlets 116. The pre-heat ring 117 is disposed above the one or more purge gas inlets 164. The one or more liners 111, 163 are disposed on an inner surface of the flow module 112 and protects the flow module 112 from reactive gases used during deposition operations and/or cleaning operations.

The gas inlet(s) 114 and the purge gas inlet(s) 164 are each positioned to flow a respective one or more process gases P1 and one or more purge gases P2 parallel to the top surface 150 of a substrate 102 disposed within the upper volume 136. The gas inlet(s) 114 are fluidly connected to one or more process gas sources 151 and one or more cleaning gas sources 153. The purge gas inlet(s) 164, 176 are fluidly connected to one or more purge gas sources 162. The one or more gas exhaust outlets 116, 128 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)).

The one or more purge gases P2, P3, can be supplied using the one or more purge gas sources 162 and can include one or more inert gases (such as one or more of argon (Ar), helium (He), air, and/or nitrogen (N₂)). In one or more embodiments, the air used from in one or more purge gas sources 162 can include dry air, saturated air, or some saturation between dry air and saturated air, such as, for example, ambient air or room air. Furthermore, the temperature(s) of the one or more purge gases P2 and/or P3, supplied by the one or more purge gas sources 162, can be reduced by directing the one or more purge gases P2 and/or P3, towards the one or more chillers 129 to provide a purge of excess heat within the upper portion 136b or the upper heat source module 155. In one or more embodiments, the one or more purge gases P2 and/or P3 may be supplied by a variable speed blower (“VSB”). The VSB can be used as one or more of the one or more purge gas sources 162. One or more cleaning gases supplied using the one or more cleaning gas sources 153 can include one or more of hydrogen (H) and/or chlorine (CI). In one or more embodiments, the one or more process gases P1 include silicon phosphide (SiP) and/or phospine (PH₃), and the one or more cleaning gases include hydrochloric acid (HCl).

The one or more gas exhaust outlets 116, 128 are further connected to or include an exhaust system, not shown. The exhaust system fluidly connects the one or more gas exhaust outlets 116, 128 and the exhaust pump 157. The exhaust system can assist in the controlled deposition of a layer on the substrate 102. The one or more gas exhaust outlets 128 may be disposed around the perimeter on a lower half 158 of the upper body 156 to enable purge gas flow towards the outer perimeter of the upper window 108.

In one or more embodiments, the processing chamber 100 includes a plate 171 (e.g., an isolation plate) having a first face 172 and a second face 173 opposing the first face 172. In one or more embodiments, the plate 171 is part of a flow guide structure. The second face 173 faces the substrate support 106. The processing chamber 100 includes the one or more liners 111, 163. An upper liner 163 includes an annular section 181 and one or more ledges 182 extending inwardly relative to the annular section 181. The one or more ledges 182 are configured to support one or more outer regions of the second face 173 of the plate 171. The upper liner 163 includes one or more inlet openings 183 and one or more outlet openings 185. In one or more embodiments, the plate 171 is in the shape of a disc, and the annular section 181 is in the shape of a ring. The plate 171 can be in the shape of a rectangle. The plate 171 divides the upper volume 136 between the substrate support 106 and the upper window 108 into a lower portion 136a and an upper portion 136b. The lower portion 136a is a processing portion and the upper portion 136b is an isolated portion. In one or more embodiments, the plate 171 is an isolation plate that at least partially physically isolates the isolated portion (e.g., the upper portion 136b) from the lower portion 136a.

The flow module 112 (which can be at least part of a sidewall of the processing chamber 100) includes the one or more gas inlets 114 in fluid communication with the lower portion 136a. The flow module 112 includes one or more second gas inlets 175 in fluid communication with the upper portion 136b. The one or more gas inlets 114 are in fluid communication with one or more flow gaps between the upper liner 163 and a lower liner 111. The one or more second gas inlets 175 are in fluid communication with the one or more inlet openings 183 of the upper liner 163.

During a deposition operation (e.g., an epitaxial growth operation), the one or more process gases P1 flow through the one or more gas inlets 114, through the one or more gaps, and into the lower portion 136a to flow over the substrate 102. During the deposition operation, one or more purge gases P2, flow through the one or more second gas inlets 175, through the one or more inlet openings 183 of the lower liner 111, and into the upper portion 136b. Also during a deposition operation, one or more purge gases P3, flow through the one or more purge gas inlets 176 and into the upper heat source module 155. The one or more purge gases P2, P3 can flow simultaneously with the flowing of the one or more process gases P1.

The flowing of the one or more purge gases P3 through the upper heat source module 155 facilitates the upper heat source module 155 purging excess heat generated from the plurality of upper heat sources 141, or from the epitaxial growth operation, and thereby maintains a desired temperature profile for the upper heat source module 155, the upper window 108, and/or the plate 171. For example, there is an indirect temperature effect on the plate 171 described below. The flowing of the one or more purge gases P2 through the upper portion 136b facilitates reducing or preventing flow of the one or more process gases P1 into the upper portion 136b that would contaminate the upper portion 136b. The one or more purge gases P2 may be directed into the one or more chillers 129 to reduce the temperature of the one or more purge gases P2 to purge excess heat within the upper portion 136b, thereby reducing or preventing flow of the one or more process gases P1 into the upper portion 136b that would otherwise contaminate the upper portion 136b and also provide a cooling effect on the plate 171.

The one or more process gases P1 are exhausted through gaps between the upper liner 163 and the lower liner 111, and through the one or more gas exhaust outlets 116. The one or more purge gases P2 are exhausted through the one or more outlet openings 185, through the same gaps between the upper liner 163 and the lower liner 111, and through the same one or more gas exhaust outlets 116 as the one or more process gases P1. The present disclosure contemplates that that one or more purge gases P2 can be separately exhausted through one or more second gas exhaust outlets that are separate from the one or more gas exhaust outlets 116.

The present disclosure also contemplates that the one or more purge gases P2 can be supplied to the purge volume 138 (through the one or more purge gas inlets 164) during the deposition operation, and exhausted from the purge volume 138.

During a cleaning operation, one or more cleaning gases flow through the one or more gas inlets 114, through the one or more gaps (between the upper liner 163 and the lower liner 111), and into the lower portion 136a. During the cleaning operation, one or more cleaning gases also simultaneously flow through the one or more second gas inlets 175, through the one or more inlet openings 183 of the upper liner 163, and into the upper portion 136b. The present disclosure contemplates that the one or more cleaning gases used to clean surfaces adjacent the upper portion 136b can be the same as or different than the one or more cleaning gases used to clean surfaces adjacent the lower portion 136a.

The processing chamber 100 facilitates separating the gases provided to the lower portion 136a from the gases provided to the upper portion 136b, which facilitates parameter adjustability. Additionally, one or more purge gases and one or more cleaning gases can be separately provided to the upper portion 136b to facilitate reduced contamination of the upper window 108 and/or, in some embodiments, the plate 171.

As shown, a controller 190 is in communication with the processing chamber 100 and is used to control processes and methods, such as the operations of the methods described herein.

The controller 190 is configured to receive data or input as sensor readings from a plurality of sensors. The sensors can include, for example: sensors that monitor growth of layer(s) on the substrate 102; sensors that monitor growth or residue on inner surfaces of chamber components of the processing chamber 100 (such as inner surfaces of the upper window 108 and/or the one or more liners 111, 163); and/or, in some embodiments, sensors that monitor temperatures of the substrate 102, the substrate support 106, the plate 171, and/or the liners 111, 163. The controller 190 is equipped with or in communication with a system model of the processing chamber 100. The system model includes a heating model, a rotational position model, and/or a gas flow model. The system model is a program configured to estimate parameters (such as a gas flow rate, a gas pressure, a processing temperature, a rotational position of component(s), a heating profile, and/or a cleaning condition) within the processing chamber 100 throughout a deposition operation and/or a cleaning operation. The controller 190 is further configured to access and/or store readings and evaluate and/or perform calculations. The readings and calculations include previous sensor readings, such as any previous sensor readings within the processing chamber 100. The readings and calculations further include the stored calculated values from after the sensor readings are measured by the controller 190 and run through the system model. Therefore, the controller 190 is configured to both retrieve stored readings and calculations as well as save readings and calculations for future use. Maintaining previous readings and calculations enables the controller 190 to adjust the system model over time to reflect a more accurate version of the processing chamber 100.

The controller 190 can monitor, estimate an optimized parameter, adjust a purge gas flow rate, adjust a chilled purge gas flow rate, initiate a reflector cooling operation, generate an alert on a display, halt a deposition operation, initiate a chamber downtime period, delay a subsequent iteration of the deposition operation, initiate a cleaning operation, detect a cleaning condition for the upper window 108 and/or the plate 171, halt the cleaning operation, adjust a heating power, and/or otherwise adjust the process recipe.

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The various operations described herein can be conducted automatically using the controller 190, or can be conducted automatically or manually with certain operations conducted by a user.

The controller 190 is configured to control the sensor devices 195, 196, 197, 198, 199, the deposition, the cleaning, the rotational position, the heating, and processing gas and purge gas flow paths prior to entry into and through the processing chamber 100, and additional chiller and heater controls, by providing an output to the controls for the heat sources, the gas flow, and the motion assembly 121. The controls include controls for the sensor devices 195, 196, 197, 198, the upper heat sources 141, the lower heat sources 143, the process gas source 151, the purge gas source 162, the chiller 129, the motion assembly 121, controls to orient gas flow paths, and the exhaust pump 157.

The controller 190 is configured to adjust the output to the controls based on the sensor readings, the system model, and the stored readings and calculations. The controller 190 includes embedded software and a compensation algorithm to calibrate measurements. The controller 190 can include one or more machine learning algorithms and/or artificial intelligence algorithms that estimate optimized parameters for the deposition operations and/or the cleaning operations (such as for adjusting a deposition operation (e.g. the process recipe), adjusting a purge gas flow rate, adjusting a chilled purge gas flow rate, initiating a reflector cooling operation, halting the deposition operation, initiating a chamber downtime period, delaying a subsequent iteration of the deposition operation, initiating a cleaning operation, halting the cleaning operation, adjusting a heating power, and/or adjusting the cleaning operation). The optimized parameter can include, for example, a pre-determined temperature on the upper window 108 that initiates a purge gas cycle to remove excess heat generated from processing to adjust the temperature of the upper window 108.

The one or more machine learning algorithms and/or artificial intelligence algorithms may implement, adjust and/or refine one or more algorithms, inputs, outputs or variables described above. Additionally or alternatively, the one or more machine learning algorithms and/or artificial intelligence algorithms may rank or prioritize certain aspects of adjustments of the process chamber 100 relative to other aspects of the process chamber 100. The one or more machine learning algorithms and/or artificial intelligence algorithms may account for other changes within the processing systems such as hardware replacement and/or degradation. In one or more embodiments, the one or more machine learning algorithms and/or artificial intelligence algorithms account for upstream or downstream changes that may occur in the processing system due to variable changes of the process chamber 100. For example, if variable “A” is adjusted to cause a change in aspect “B” of the process, and such an adjustment unintentionally causes a change in aspect “C” of the process, then the one or more machine learning algorithms and/or artificial intelligence algorithms may take such a change of aspect “C” into account. In such an embodiment, the one or more machine learning algorithms and/or artificial intelligence algorithms embody predictive aspects related to implementing the process chamber 100 and/or the method. The predictive aspects can be utilized to preemptively mitigate unintended changes within a processing system.

In one or more embodiments, the controller 190 automatically conducts the operations described herein without the use of one or more machine learning algorithms or artificial intelligence algorithms. In one or more embodiments, the controller 190 compares measurements to data in a look-up table and/or a library to determine if a purge gas flow rate and/or a chilled purge gas flow rate are to be conducted, and/or if a reflector cooling operation is to be conducted. The controller 190 can stored measurements as data in the look-up table and/or the library.

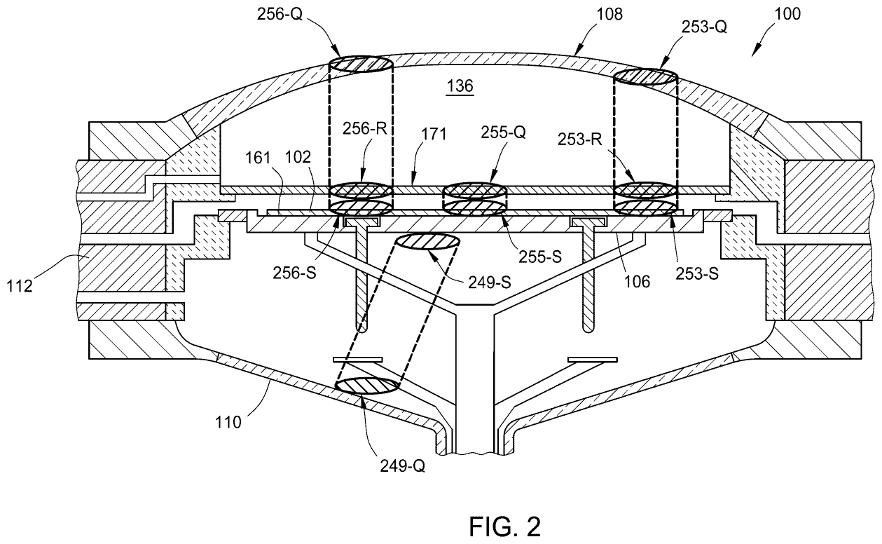

FIG. 2 is a schematic view of the temperature measurement sites by the sensing devices shown in FIG. 1, according to one or more embodiments. Temperature measurement sites 249-Q, 249-S, 253-Q, 253-R, 253-S, 255-Q, 255-S, 256-Q, 256-R, 256-S correspond to the capabilities of measurements by sensor devices 196, 196, 197, 198. For example, in one or more embodiments, the lower sensor device 195 (shown in FIG. 1) is configured to measure temperatures at site 249-Q (e.g., at a middle peripheral region of the lower window 110) and/or site 249-S(e.g., at a middle peripheral region of the lower surface of the substrate support 106). In one or more embodiments, a first upper sensor device 196 (shown in FIG. 1) is configured to measure temperatures at site 255-Q (e.g., at a central region of the plate 171) and/or site 255-S(e.g., at a central region of the substrate 102 and/or a central region of the upper surface 161 of the substrate support 106). In one or more embodiments, a second upper sensor device 197 (shown in FIG. 1) is configured to measure temperatures at site 253-Q (e.g., at an outer peripheral region of the upper window 108), at site 253-R (e.g., at an outer peripheral region of the plate 171), and/or site 253-S(e.g., at an outer peripheral region of the substrate 102 and/or an outer peripheral region of the upper surface 161 of the substrate support 106). In one or more embodiments, a third upper sensor device 198 (shown in FIG. 1) is configured to measure temperatures at site 256-Q (e.g., at an outer peripheral region of the upper window 108), at site 256-R (e.g., at an outer peripheral region of the plate 171), and/or site 256-S(e.g., at an outer peripheral region of the substrate 102 and/or an outer peripheral region of the upper surface 161 of the substrate support 106). The sensor devices 195, 196, 197, 198 may be positioned and/or oriented differently than what is shown in FIG. 1 and FIG. 2, while still capable of measuring temperatures at a site on, for example, the plate 171, a site on one or more of the windows (e.g., upper window 108 and/or lower window 110), and/or a site on one of the surfaces of substrates support 106 (e.g., upper surface 161 and/or lower surface) and/or the substrate 102.

Each of the sensor devices 195, 196, 197, 198 may be adapted to detect energy (e.g., radiation, such as light) at two or more (such as three or more) different wavelength ranges. For example, in one or more embodiments the two or three wavelength ranges of the upper sensor devices 196, 197, 198 are selected to be (1) a wavelength range at which the plate 171 is absorptive (e.g., about 2.48 microns to about 2.98 microns, such as about 2.7 microns), (2) a wavelength range at which the substrate support 106 and/or the substrate 102 is absorptive (e.g., about 3.17 microns to about 3.67 microns, such as about 3.4 microns), and (3) a wavelength range at which the upper window 108 and/or the lower window 110 is absorptive (e.g., about 4.75 microns to about 5.25 microns, such as about 5.0 microns).

The temperature measurements made by each of the sensor devices 195, 196, 197, 198 can be used to monitor component temperatures (such as, for example, plate 171 temperature) within the process chamber 100.

In one or more embodiments, the upper window 108 includes a first quartz. In one or more embodiments, the plate 171 includes a second quartz. The first quartz has a first hydroxyl concentration of less than 100 parts-per-million ppm). In one or more embodiments, the first hydroxyl concentration is 30 ppm or less, such as within a range of about 5 ppm to about 30 ppm. The second quartz has a second hydroxyl concentration of more than 750 parts-per-million (ppm). In one or more embodiments, the second hydroxyl concentration is 900 ppm or more. In one or more embodiments, the upper window 108 is formed of the first quartz and the plate 171 is formed of the second quartz. Other window(s), such as the lower window 110, can include the first quartz. For example, the lower window 110 can be formed of the first quartz. Using the first quartz and the second quartz facilitates accurately and efficiently measuring temperatures of the plate 171 and the substrate support 106 (and/or the substrate 102) during processing. As an example, the plate 171 having the higher second hydroxyl concentration facilitates accurately and efficiently measuring temperatures for the plate 171 using the second wavelength. The hydroxyl concentrations can be affected, for example, by the water content and/or contamination content in the respective first quartz or second quartz. The higher hydroxyl concentration of the second quartz involves a lower transmission of energy having the second wavelength. The higher hydroxyl concentration of the second quartz involves a higher transmission of energy having the first wavelength. In one or more embodiments, the second quartz is synthetic quartz, such as quartz formed using a soot process. In one or more embodiments, the first quartz is a fused quartz, such as electrically fused quartz. Other quartz materials (such as flame fused quartz) are contemplated for the first quartz and/or the second quartz.

Using the first quartz and the second quartz facilitates enhanced signal-to-noise ratios for the measurements. Using the first quartz, thermal non-uniformities affected by temperature gradients of the upper window 108 are reduced or eliminated. For example, gradients of the hydroxyl concentration across a diameter of the first quartz are reduced or eliminated to facilitate enhanced heating uniformity. As recited herein, the hydroxyl concentration refers to a parts-per-million (ppm) measurement of hydroxyl groups (e.g., groups including an oxygen atom covalently bonded to a hydrogen atom) in or on the respective quartz material. In one or more embodiments, the ppm measurement of the hydroxyl concentration is a measured concentration of hydroxyl groups relative to all other materials (such as contaminants and/or quartz) present on the respective quartz surfaces of the first quartz or the second quartz. In one or more embodiments, the measurement of the hydroxyl concentration is conducted by X-ray photoelectron spectroscopy (XPS) and provided in the unit of ppm. The present disclosure contemplates that other measurement techniques, such as glow discharge mass spectroscopy (GDMS), may be used to measure the ppm values of the hydroxyl concentration.

In one or more embodiments, the first quartz is transmissive for the first wavelength and the second wavelength discussed herein. In one or more embodiments, the second quartz is transmissive for the first wavelength and is absorptive for the second wavelength. In one or more embodiments, the material of the substrate support 106 is absorptive for the first wavelength. The first quartz facilitates reduced absorption and increased transmission (for the first wavelength and the second wavelength), and reduced power expenditures for heating. The first quartz can have a higher transmission (e.g., by over 5%) for infrared light relative to other materials, at a temperature of about 1000 degrees Celsius. The first quartz can facilitate for example, a power savings of over 5 KW per 100 KW expended. The first quartz facilitates increased heat ramp rates and increased throughput.

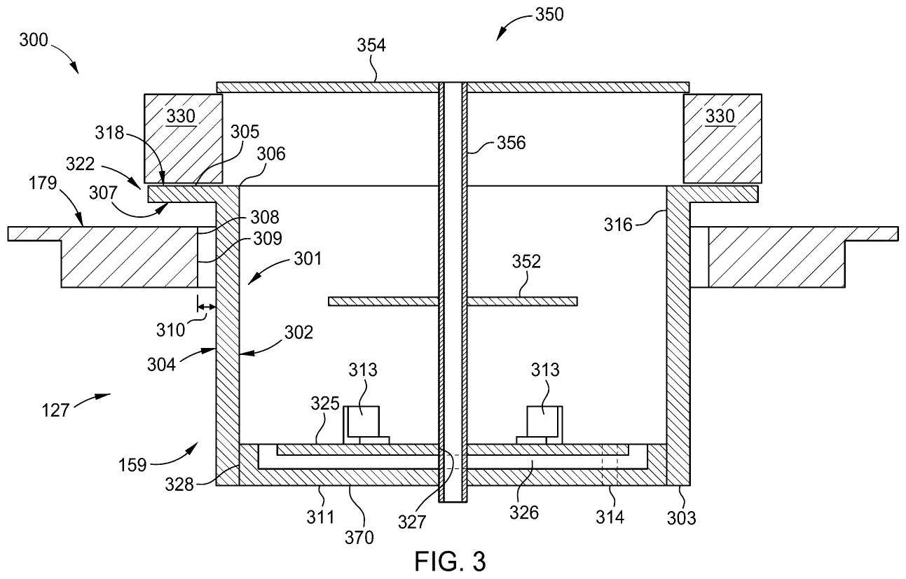

FIG. 3 illustrates the cross sectional view of an inner reflector assembly 300, according to one or more embodiments. While the foregoing will discuss embodiments of an upper reflector assembly 300, it should be understood that the same construction may apply to embodiments in which a lower reflector is utilized near the lower heat sources module 145. The reflector assembly 300 includes the upper shell assembly 159, which includes the inner reflector 127, a ring 330 (e.g., an arresting ring), and a reflector 179 (e.g., a ring reflector). In one or more embodiments, a baffle structure 350 in within the upper shell assembly 159. The upper shell assembly 159 includes a shell body 301 and a shell flange 305. The shell body 301 includes a cylindrical shape with an inner diameter surface 302, and an outer diameter surface 304, a proximate end 316, and a distal end 303. The shell flange 305 includes an upper surface 318, a lower surface 307, an inner diameter edge 306, and an outer diameter edge 322 that extends radially outward from the inner diameter surface 302 of the shell body 301. The shell flange 305 is connected to the proximate end 316 of the shell body 301 at the inner diameter edge 306 as a one-piece monolithic structure. The upper shell assembly 159 includes a baffle 311 (e.g., a lower baffle) located at the distal end 303 of the shell body 301. The lower baffle 311 may be disk-shaped having a top surface 325 and a bottom 370, with an inner edge 327 and an outer edge 328. The lower baffle 311 includes a fluid channel 326 (e.g., a cooling fluid channel) formed within. The lower baffle 311 may be connected to the distal end 303 of the shell body 301 as a one-piece monolithic structure. The top surface 325 is configured to support sensor devices, such as sensor devices 195, 196, 197, 198, and/or 199, as illustrated in FIG. 1.

In one or more embodiments, the baffle structure 350 includes a middle baffle 352, a top baffle 354, and a cylindrical sensor tube 356. The middle baffle 352 and the top baffle 354 have a disk shape and are disposed around a common centerline of the cylindrical sensor tube 356. The baffle structure 350 may be constructed of the same material as the ring reflector 179, or other suitable material, such as aluminum.

The lower baffle 311 may be connected to the inner diameter surface 302 of the shell body 301. The connector 313 may be a bracket or structure suitable for connecting the lower baffle 311 to the shell body 301, such as a weld connection. In one or more embodiments, the connectors 313 are a web of material extending between the outer edge 328 of the lower baffle 311 and the inner diameter surface 302 at the distal end 303 of the shell body 301 when the shell body 301 and lower baffle 311 are fabricated as a monolithic structure. Furthermore, it is contemplated the upper shell assembly 159, including the optional lower baffle 311 and baffle structure 350, are formed as a monolithic structure. The lower baffle 311 is constructed of the same material as the ring reflector 179 and coated similarly. Furthermore, the lower baffle 311 may have a cut out 314 that enables the sensor devices 195, 196, 197, 198 to have a line of sight towards the intended temperature measurement location. While one cut out 314 is illustrated, it is understood that a cut out may be available for each of the sensor devices 195, 196, 197, 198 as shown in FIG. 1.

The upper shell assembly 159, including the lower baffle 311 and the arresting ring 330, may be constructed of aluminum with a reflective gold coating, polished aluminum, or gold. In one or more embodiments, the arresting ring 330 may be constructed with a non-reflective surface. The ring reflector 179 may be constructed of the same material as the upper shell assembly 159. As shown, the upper shell assembly 159 is configured to be inserted adjacent to the inner edge 308 of the ring reflector 179. The outer diameter surface 304 of shell flange 305 is less than the inner diameter surface 309 of the ring reflector 179, creating a gap 310 between the ring reflector 179 and the upper shell assembly 159. In one or more embodiments, the ring reflector is concentrically disposed radially outward of the outer diameter surface 304 of the upper shell assembly 159. The gap 310 may be about 1 mm to about 10 mm, such as about 2 mm to about 8 mm, such as about 3 mm to about 6 mm, such as about 3 mm to about 5 mm.

The arresting ring 330 is configured to impede fluid flow into the upper shell assembly 159. In some embodiments, the arresting ring 330 has a height configured to impede up to 100 percent, such as up to 95 percent, such as up to 90 percent, such as up to 85 percent, such as up to 80 percent of fluid into the upper shell assembly 159. In some embodiments, the arresting ring 330 may be an actuatable component configured to throttle and vary the amount of fluid allowed to enter the upper shell assembly 159. In some embodiments, the monolithic lower baffle 311 arrests the fluid flow into the upper shell assembly 159. In some embodiments, the arresting ring 330 may reduce or prevent suction within the upper shell assembly 159 while reducing fluid flow over the upper shell assembly 159. For example, fluid flow that would otherwise flow through the upper shell assembly 159 will now be redirected, as shown in FIG. 1, P3.

The lower baffle 311 includes a fluid channel 326 formed therein. FIG. 3 illustrates the fluid channel 326 inlet and the fluid channel 326 outlet as being positioned 180 degrees from each other. It is contemplated that the spacing between the fluid channel inlet and outlet may be substantially next to each other or some distance in between. The fluid channel 326 may traverse along a path suitable to provide cooling to sensor devices 195, 196, 197, 198, and/or 199, as needed. In one or more embodiments, the fluid channel 326 may be a single annular enclosure that follows the annular body of the lower baffle 311. In another embodiment, the fluid channel 326 may be a divided annular enclosure containing multiple flow paths that follow a disk shape of the lower baffle 311. In another embodiment, the fluid channel 326 inlet and the fluid channel 326 outlet may be side, top, or bottom entry and exit ports on the lower baffle 311. Chamber processing operations may overheat the sensor devices 195, 196, 197, 198, and/or 199 sheltered from direct thermal energy generated within the upper heat source module 155. To minimize overheating of the sensor devices 195, 196, 197, 198 and/or 199, a cooling fluid is provided to cool the inside of the upper shell assembly 159 that houses the sensors. The cooling fluid may be water, air, fluorinated heat transfer fluid, or some combination suitable fluid to remove heat from the lower baffle 311.

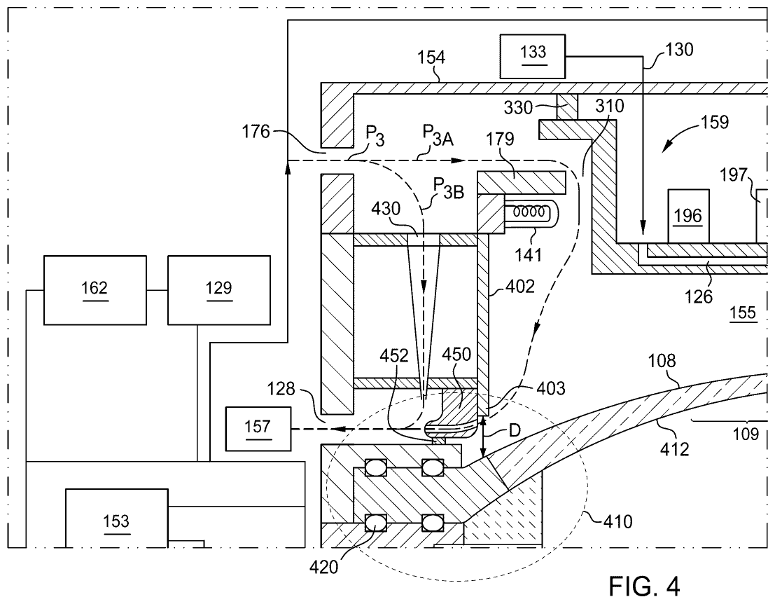

FIG. 4 illustrates an enlarged schematic side cross-sectional view of a processing chamber 100, according to one or more embodiments. As mentioned above, temperature monitoring and control of chamber components (such as the window 108) is difficult, since chamber components can be subjected to various temperature gradients from multiple heat or cooling sources. For example, an epitaxial growth deposition process may generate heat from the plurality of upper heat sources 141 within the upper heat source module 155 such that a base (such as a lamp base to which a lamp bulb is mounted) of each upper heat source 141 is heated to a base temperature that is about 350 degrees Celsius or less. The present disclosure contemplates that the base temperature can be lower, such as lower than about 55 degrees Celsius. The heat can overheat the inner reflector 127 and housed devices. However, the temperature of the inner reflector 127, measureable by the optical device 199, can initiate the inner reflector 127 cooling cycle operation to maintain optical device integrity, causing a cooled zone in the upper heat source module 155 to maintain the inner reflector 127 at a temperature below about 55 degrees Celsius. An increase in the temperature of the upper heat source module 155 may be performed by lessening a purge gas provided from the one or more purge gas sources 162, such as a VSB. In one or more embodiments, as discussed below, cooling of the upper heat source module 155 may be caused by, for example, increasing an air purge provided from the one or more purge gas sources 162, such as a VSB. In one or more embodiments, as discussed below, a chilled purge gas is used to cool the upper heat source module 155.

These dynamic temperature gradients may affect chamber component temperature monitoring and control. For example, the heat from within the upper heat source module 155 radiates through the upper window 108 and affects the temperature of, for example, substrate support 106 and/or the substrate 102.

Typically, as the temperature of the upper window 108 is affected through a heating or cooling processing operation within the upper body 156, undesired depositions may occur on the bottom surface 412 of the upper window 108 facing the upper portion 136b. To reduce undesired depositions requiring frequent cleaning operations, a purge gas flow path, P3A, is formed along the perimeter of the upper window 108, creating a cooling zone 410 to cool the upper heat sources 141 and the upper window 108 perimeter without affecting the temperature of the central portion 109 of the upper window 108. In other words, because the flow path P3A travels through the cooling zone 410, but not proximate to the central portion 109, the central portion 109 retains thermal energy. By maintaining the temperature of the central portion 109 of the upper window 108, undesired depositions are significantly reduced on the bottom surface 412, near the central portion 109 of the upper window 108, facing the upper portion 136b. The combination of the reflector assembly 159 coupled to the arresting ring 330, directs the flow path P3A through the gap 310 allowing for the fluid to flow towards the one or more gas exhaust outlets 128, substantially avoiding the central portion 109 of the upper window 108.

Additionally, the flow path P3A cools the seals 420 coupled to the upper window 108. The seals 420 experience various temperature fluctuations of the thermal energy generated by the upper heat sources 141. Over time, the seals 420 may degrade causing premature failure of the chamber component. Accordingly, the flow path P3A may extend the useful life of the seals 420, reducing processing costs.

Furthermore, the specific design of the flow path P3A enables the cleaning efficiency of the undesired depositions to be greatly increased, since a cleaning cycle may not require a temperature stabilization period to compensate for the thermal energy that would otherwise be lost by a conventional cross flow path within the upper body 156 (not shown). Therefore, the perimeter flow design of the flow path P3A retains more thermal energy than in conventional upper body 156 cooling operations, allowing for faster cleaning cycle turnaround times.

A vertical wall design of an outer reflector 402 extending toward the upper window 108 is also illustrated in FIG. 4. The outer reflector 402 is disposed below, or under, the ring reflector 179 and the upper heat sources 141. The outer reflector 402 may be coupled to either the ring reflector 179 and/or the upper heat sources 141 to suspend the outer reflector 402 above the upper window 108. The outer reflector 402 has a distal end 403 facing the upper window 108. The distal end 403 has a distance D from the upper window 108 of about 20 mm to about 35 mm, such as about 25 mm to about 30 mm. The distance D enables the purge gas to concentrate along the outer perimeter of the upper window. In one or more embodiments, the concentration of purge gas as it flows along flow path P3A maximizes the cooling effect on the outer perimeter of the upper window 108 and the seals 420.

The one or more purge gases P3 are divided into at least two fluid paths: flow path P3A (discussed above) and flow path P3B. In one or more embodiments, the flow division may be controlled by the actuatable arresting ring 330, allowing more air flow towards the upper shell assembly 159. In one or more embodiments, the flow division may be controlled by the spatial opening of the gap 310. Because flow follows a path of least resistance, it is contemplated that other methods of flow divisions are achievable by use of a force, for example, adjusting the flowrate of the VSB and/or adjusting the openings of the intended flow paths as mentioned. In one or more embodiments, the majority of the flow path is configured to flow downward into a separator 430. The separator is disposed radially outward of the outer reflector 402. The separator 430 is a truncated conical shaped component configured to inject the purge gas P3 following the fluid path P3B, directly downward to the clamp 450, the clamp ring 452, and the seals 420. The clamp 450 and the clamp ring 452 also experience thermal energy from processing operations, similar to seals 420. By providing a direct flow of purge gas to the clamp 450, the clamp ring 452, and the seals 420, the life of the components is extended.

Adjusting the temperature of a chamber component may be performed by methods such as incremental purging of the upper heat source module 155 with fluid to remove excess heat generation, raising or lowering the heated substrate support 106, additional heater placements, and/or cooled purge gases flowing the flow paths P3A, P3B.

The variable speed blower (VSB) provides a fluid flow path (represented as purge gas, P3) providing a back pressure of up to about 2 kilo Pascals (kPa) in the upper heat source module 155. It is to be understood that a reduction of back pressure will increase a cooling effect (and vice versa) and therefore, the distribution of air may be optimized for cooling other chamber components. For example, the VSB allows for incremental reductions in air flow (i.e., increased back pressure) to reduce the air throughput within the upper heat source module 155 while maintaining proper air throughput to, for example, the upper portion 136b and/or the purge volume 138. In one or more embodiments, the VSB may be reduced by increments smaller than 25 percent increments, such as about 10 percent increments, about 5 percent increments, or about 1 percent increments. Incrementally increasing the VSB flow rate can beneficially provide a cooling of the upper window 108 perimeter. In other words, the heating of the upper heat source module 155 may be performed by incrementally reducing air flow and similarly, the cooling of the upper heat source module 155 may be performed by incrementally raising the reduced air flow.

Benefits of the present disclosure include accurate, quick, efficient, and automatic detection and adjustment of the temperature within the cooling zone 410 of the upper window 108 and/or the temperature of the inner reflector 127; adjustability of parameters (such as temperatures, gas flow paths, gas flow rates, and/or gas pressures) across a variety of operation conditions (such as low rotation speeds, high pressures, and/or low flow rates); broader and/or more modular ranges of adjustability; and increased deposition uniformity. Benefits of the present disclosure also include reduced chamber cleaning frequency, reduced chamber footprints; reduced or eliminated chamber component contamination; increased component lifespan; reduced chamber downtime; increased throughput; and enhanced deposition repeatability.

It is contemplated that one or more aspects disclosed herein may be combined. As an example, one or more aspects, features, components, operations and/or properties of the processing chamber 100, the controller 190, the one or more sensor devices 195, 196, 197, 198, 199, and/or the inner reflector assembly 300, may be combined. For example, the operations and/or parameters described in relation to FIGS. 1-4 can be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A semiconductor processing kit, comprising:
a reflector assembly, the reflector assembly configured to support one or more sensing devices therein, the reflector assembly comprising:
a body having a top surface and a volume at least partially defined by an inner surface and an outer surface;
a baffle; and
a fluid channel disposed within the baffle, the fluid channel configured to flow a fluid to adjust a temperature of the one or more sensing devices;
a ring disposed on the top surface, the ring configured to reduce a flow of a fluid into the volume; and
a reflector concentrically disposed radially outward of the outer surface and creating a gap that allows the fluid to partially flow between the inner surface of the reflector and the outer surface.

2. The processing kit of claim 1, further comprising a heater assembly, the heater assembly configured to support one or more heaters therein.

3. The processing kit of claim 2, further comprising an outer reflector coupled to the heater assembly, wherein a flow path along a perimeter of a chamber window is defined by the reflector assembly, the ring, and the outer reflector.

4. The processing kit of claim 3, wherein air is configured to flow along the flow path to cool at least one of the one or more heaters, a perimeter of the chamber window, and/or a chamber window seal.

5. The processing kit of claim 3, further comprising a separator disposed radially outward of the outer reflector, the separator configured to directly flow a fluid to a component.

6. The processing kit of claim 5, wherein the component comprises a chamber window seal.

7. The processing kit of claim 5, wherein the component comprises a clamping ring.

8. The processing kit of claim 1, wherein the fluid channel is configured to maintain the one or more sensing devices at a temperature less than about 55 degrees Celsius.

9. The processing kit of claim 4, wherein the outer reflector is disposed under the heater assembly and disposed a distance above the chamber window.

10. The processing kit of claim 9, wherein the distance is about 20 mm to about 35 mm.

11. The processing kit of claim 3, wherein the chamber window is thermally transmissive.

12. A processing system, comprising:
a chamber body comprising one or more sidewalls at least partially defining an internal volume;
a substrate support disposed in the internal volume;
a lid;
a reflector body supported by the lid and at least partially defining a volume;
an arresting ring disposed between the reflector body and the lid, the arresting ring configured to reduce a flow of a fluid into the volume; and
a ring reflector concentrically disposed radially outward of the reflector body and defining a gap that allows the fluid to partially flow between the ring reflector and the reflector body.

13. The system of claim 12, further comprising:
a heater assembly, the heater assembly configured to support one or more heaters therein to heat the internal volume; and
an outer reflector coupled to the heater assembly, wherein a flow path along a perimeter of a chamber window is defined by the reflector body, the arresting ring, and the outer reflector, the chamber window, the one or more sidewalls, and the lid at least partially defining the internal volume.

14. The system of claim 13, further comprising a separator disposed radially outward of the outer reflector, the separator configured to directly flow a fluid to a component.

15. The system of claim 14, wherein the component comprises a chamber window seal or a clamping ring.

16. The system of claim 12, wherein the reflector body has a top surface and a volume at least partially defined by an inner surface and an outer surface, and the system further comprises:
a baffle; and
a fluid channel disposed within the baffle, the fluid channel configured to flow a fluid to adjust a temperature of one or more sensing devices, wherein the fluid channel is configured to maintain the one or more sensing devices at a temperature less than about 55 degrees Celsius.

17. The system of claim 13, wherein the outer reflector is disposed under the heater assembly and disposed a distance above a chamber window, wherein the distance is about 20 mm to about 35 mm.

18. A method of adjusting a temperature of a processing chamber component, comprising:
flowing a purging fluid into an internal volume separate from a processing volume;
flowing a first portion of the purging fluid through a gap between a reflector assembly and a ring reflector disposed within the internal volume;
flowing a second portion of the purging fluid through a separator disposed within the internal volume and radially outward of the ring reflector; and
exhausting the first portion of the purging fluid and the second portion of the purging fluid.

19. The method of claim 18, wherein the separator has a truncated conical shaped component configured to guide the second portion of the purging fluid to the one or more exhausts.

20. The method of claim 18, wherein the separator is configured to directly flow the purging fluid to a plate seal and/or a chamber clamp ring.
